(19) United States
(12) Patent Application Publication
(10) Pub. No.: US 2021/0117315 A1
(43) Pub. Date: Apr. 22, 2021

(54) MEMORY CONTROLLER AND FLASH MEMORY SYSTEM

(71) Applicant: TDK CORPORATION, Tokyo (JP)

(72) Inventor: Kenichi TAKUBO, Tokyo (JP)

(73) Assignee: TDK CORPORATION, Tokyo (JP)

(21) Appl. No.: 17/036,363

(22) Filed: Sep. 29, 2020

(30) Foreign Application Priority Data
Oct. 21, 2019 (JP) 2019-192320

(51) Int. Cl. G06F 12/02; G06F 12/14; G06F 12/0882; G06F 13/16

(52) U.S. Cl. CPC G06F 12/0246; G06F 12/1483; G06F 2212/7201; G06F 13/1668; G06F 12/0882

(57) ABSTRACT

This memory controller controls access to a flash memory in response to commands from a host system. The memory controller identifies a physical block to be accessed among a plurality of physical blocks included in the flash memory, based on management information associated with each of the plurality of physical blocks. Furthermore, when data stored in one physical block among the plurality of physical blocks is transferred to a different physical block among the plurality of physical blocks that is different from the one physical block, the memory controller changes management information associated with the different physical block to management information associated with the one physical block.

### CROSS-REFERENCE TO RELATED APPLICATION

This application claims the benefit of Japanese Patent Application No. 2019-192320, filed on Oct. 21, 2010, the entire disclosure of which is incorporated by reference herein.

### FIELD

The present disclosure relates to a memory controller and a flash memory system.

### BACKGROUND

In recent years, flash memory has been actively developed and has become popular as a non-volatile recording medium.

In memory systems using flash memory, correspondences between the logical addresses assigned by the host system and physical addresses in the flash memory are managed. For example, Unexamined Japanese Patent Application Publication No. 2012-68765 discloses a memory controller that manages the correspondences between logical addresses and physical addresses in units of pages, which are processing units of data read operations and data write operations.

In systems that use flash memory, data is frequently transferred between physical blocks when data corruption is significant or when overwriting data stored in the flash memory. Physical blocks are processing units of data deletion operations. When transferring data between physical blocks, the addresses of the transferred data before and after the transfer must be accurately managed.

However, updating, piece by piece, the address management information of the data that is stored in all of the physical pages in the physical blocks, each time data is transferred between the physical blocks results in an increase in the amount of updating of the address management information. Increasing the amount of updating of the address management information leads to declines in system performance and shortening of the life of the flash memory. As such, there is a need to efficiently manage addresses when transferring data between physical blocks.

The present disclosure is made with the view of the above situation, and an objective of the present disclosure is to provide a memory controller and a flash memory system capable of efficiently managing addresses when transferring data between physical blocks.

### SUMMARY

A memory controller according to a first aspect of the present disclosure that achieves the objective described above is:

a memory controller that controls access to a flash memory in response to a command from a host system, the memory controller including:

a microprocessor that executes access processing for controlling the access to the flash memory and region management for managing a storage region in accordance with the access processing; wherein

in the access processing, a physical block to be accessed among a plurality of physical blocks included in the flash memory is identified based on management information associated with each of the plurality of physical blocks, and

in the region management, when data stored in one physical block among the plurality of physical blocks is transferred to a different physical block among the plurality of physical blocks that is different from the one physical block, management information associated with the different physical block is changed to management information associated with the one physical block.

In the access processing, a storage location of data to be accessed in the flash memory may be identified based on a first table that defines, using the management information, a correspondence between a logical address corresponding to each piece of data stored in the flash memory and a storage location of the each piece of data, and a second table that defines correspondences between the plurality of physical blocks and the management information, and in the region management, when the data stored in the one physical block is transferred to the different physical block, the management information associated with the different physical block in the second table may be changed to the management information associated with the one physical block.

The first table may define, using the management information, the correspondence between a logical page corresponding to the each piece of data and a physical page on which the each piece of data is stored, and in the access processing, a physical block including the physical page corresponding to the logical page to be accessed may be identified based on the second table, and the physical page is accessed.

A flash memory system according to a second aspect of the present disclosure that achieves the objective described above includes the memory controller described above, and the flash memory.

According to the present disclosure, it is possible to efficiently manage addresses when transferring data between physical blocks.

### BRIEF DESCRIPTION OF THE DRAWINGS

A more complete understanding of this application can be obtained when the following detailed description is considered in conjunction with the following drawings, in which:

FIG. 1 is a block diagram of a flash memory system according to an embodiment of the present disclosure;

FIG. 2 is a drawing schematically illustrating the structure of address space of a flash memory according the embodiment;

FIG. 3 is a drawing illustrating the correspondence between address space on a host system side and the address space on the flash memory side in the embodiment;

FIG. 4 is a drawing illustrating an example of a logical-physical translation table of the embodiment;

FIG. 5 is a drawing illustrating an example of a management number table of the embodiment;

FIG. 6 is a flowchart illustrating the flow of data write processing executed in the flash memory system according the embodiment;

FIG. 7 is a drawing illustrating an example in which the logical-physical translation table illustrated in FIG. 4 is updated when data is written to the flash memory;

FIG. 8 is a flowchart illustrating the flow of data transfer processing executed by the flash memory system according to the embodiment;

FIG. 9 is a drawing illustrating an example in which the management number table illustrated in FIG. 5 is updated when data is transferred between physical blocks;

FIG. 10 is a drawing illustrating an example of a table for managing virtual blocks; and

FIG. 11 is a drawing illustrating an example of a management number table for a case in which virtual blocks are used.

### DETAILED DESCRIPTION

Hereinafter, embodiments of the present disclosure are described with reference to the drawings. In these drawings, identical or corresponding components are marked with the same reference numerals.

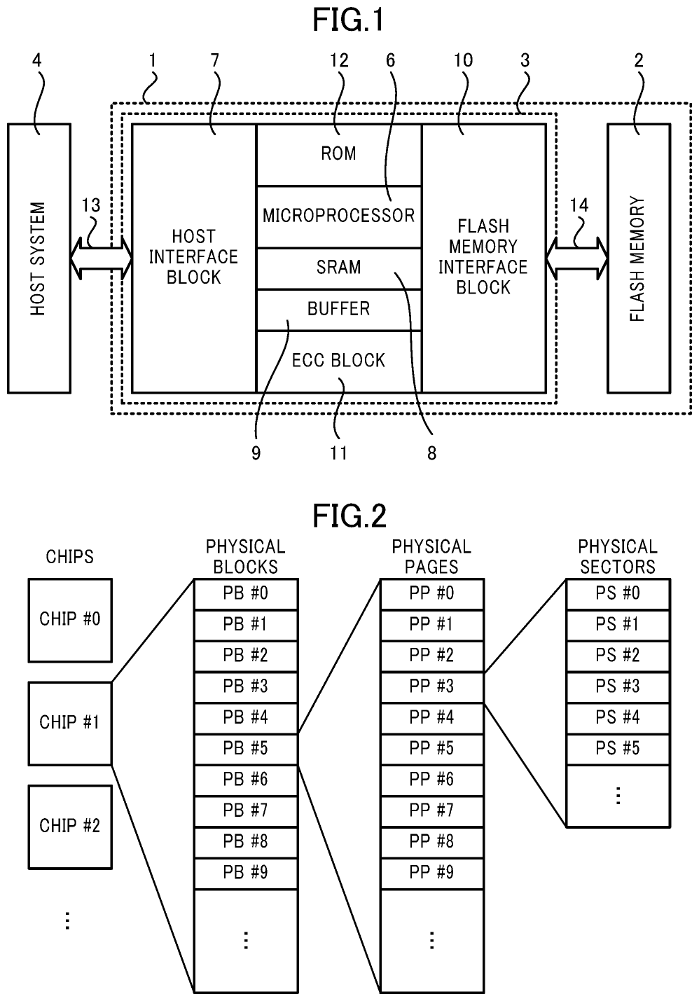

FIG. 1 is a block diagram schematically illustrating a flash memory system 1 according to an embodiment of the present disclosure. As illustrated in FIG. 1, the flash memory system 1 includes a flash memory 2 and a memory controller 3 that controls the flash memory 2. The memory controller 3 is connected to the flash memory 2 via an internal bus 14.

The flash memory system 1 is connected to a host system 4 via an external bus 13. The host system 4 includes a central processing unit (CPU) for controlling the overall operations of the host system 4, a companion chip responsible for the exchange of information with the flash memory system 1, and the like (all not illustrated in the drawings). In one example, the host system 4 is an information processing device such as a personal computer or a digital still camera that processes a variety of information such as text, speech, and images.

The memory controller 3 controls access to the flash memory 2 in response to commands from the host system 4. As illustrated in FIG. 1, the memory controller 3 includes a microprocessor 6, a host interface block 7, a static random access memory (SRAM) 8, a buffer 9, a flash memory interface block 10, an error correcting code (ECC) block 11, and a read-only memory (ROM) 12. Hereinafter, the various functional blocks will be described.

The microprocessor 6 controls the overall operations of the memory controller 3 in accordance with programs stored in the ROM 12. For example, the microprocessor 6 reads a command set that defines various processes or the like from the ROM 12, supplies the read command set to the flash memory interface block 10, and causes the flash memory interface block 10 to execute the processes. The programs stored in the ROM 12 may consist of only a program (boot loader) for reading actual programs from the flash memory 2 to the SRAM 8. In such a case, the actual control is carried out based on the programs read to the SRAM 8.

The host interface block 7 controls the sending and receiving of data, address information, status information, external commands, and the like carried out to and from the host system 4. The external commands are commands whereby the host system 4 instructs the flash memory system 1 to execute processes. The data and the like that is supplied to the flash memory system 1 from the host system 4 enters into the flash memory system 1 (for example, into the buffer 9) via the host interface block 7 serving as an entrance. The data and the like supplied to the host system 4 from the flash memory system 1 is supplied to the host system 4 via the host interface block 7 serving as an exit.

The SRAM 8 is volatile memory in which information required for the controlling of the flash memory 2 is temporarily stored. In one example, an address conversion table, a bad block table and the like required for accessing the flash memory 2 are held in the SRAM 8 and are updated on the SRAM 8. The address conversion table is a table for managing correspondences between logical addresses and physical addresses. The bad block table is a table for managing bad blocks. In a case in which a control program is stored in the flash memory 2, the control program is read from the flash memory 2 at start-up and held in the SRAM 8.

Data read from the flash memory 2 and data to be written to the flash memory 2 is temporarily stored in the buffer 9. The data read from the flash memory 2 is held in the buffer 9 until the host system 4 becomes capable of receiving the data. The data to be written to the flash memory 2 is held in the buffer 9 until the flash memory 2 is in writable state.

The flash memory interface block 10 controls the sending and receiving of data, address information, status information, internal commands, and the like carried out to and from the flash memory 2. The internal commands are commands whereby the memory controller 3 instructs the flash memory 2 to execute processes. The flash memory 2 operates in accordance with the internal commands given by the memory controller 3.

The ECC block 11 generates an error correcting code that is added to the data to be written to the flash memory 2. Additionally, the ECC block 11 detects and corrects errors included in the read data based on the error correcting code that is added to the data read from the flash memory 2.

The ROM 102 is a non-volatile memory device in which control programs, which define procedures of processes carried out by the microprocessor 6 and the like, are stored. In one example, a program defining a processing procedure for creating an address conversion table, or the like, is stored in the ROM 102. Note that, in some cases, only a boot loader is stored in the ROM 102, and the control programs are stored in the flash memory 2.

The flash memory 2 is a non-volatile memory. The flash memory 2 includes a register, and a memory cell array in which a plurality of memory cells are arranged (all not illustrated in the drawings). The flash memory 2 copies data between the register and the memory cell array, and carries out writing or reading of the data. The data to be written to the memory cell array, or the data to be read from the memory cell array, is temporarily held in the register.

The memory cell array includes a plurality of memory cell groups and word lines. Each of the memory cell groups includes a plurality of memory cells connected in series. The word lines are for selecting specific memory cells from the memory cell groups. Writing of data from the register to the selected memory cells, or reading of data from the selected memory cells to the register is carried out between the register and the memory cells selected via the word lines.

The memory cells of the memory cell array include a MOS transistor provided with two gates. In this case, the upper gate and the lower gate are respectively referred to as a control gate and a floating gate. Writing of data is carried out by injecting a charge (electrons) into the floating gate, and deletion of data is carried out by discharging the charge (electrons) from the floating gate.

Since the floating gate is surrounded by an insulator, injected electrons are held for an extended period of time. When injecting electrons into the floating gate, high voltage, with the control gate as the high potential side, is applied between the control gate and the floating gate. In contrast, when discharging electrons from the floating gate, high voltage, with the control gate as the low potential side, is applied between the control gate and the floating gate.

Here, a state in which electrons are injected into the floating gate is a written state, and corresponds to a logical value of “0”. A state in which electrons are discharged from the floating gate is a deleted state, and corresponds to a logical value of “1”.

In a memory cell array of 3D-NAND type flash memory, there are cases in which the cell structure of a charge trap structure is used. In this cell structure, electrons are injected into defects (trapping layers) that exist inside a gate insulating film (silicon nitride film), or electrons are removed from the trapping layers.

The memory controller 3 transfers, to the flash memory 2, data supplied from the host system 4, and writes the transferred data to the memory cell array via the register in the flash memory 2. Additionally, the memory controller 3 reads the data written to the memory cell array via the register, and provides the read data to the host system 4. The flash memory 2 writes data to the memory cell array or reads data from the memory cell array in accordance with commands given by the memory controller 3.

FIG. 2 schematically illustrates the configuration of the flash memory 2. As illustrated in FIG. 2, the flash memory 2 is configured from “chips”, “blocks (physical blocks)”, “pages (physical pages)”, and sectors “physical sectors).” The flash memory 2 includes at least one chip, and each chip includes a plurality of physical blocks.

Physical blocks are processing units of data deletion operations carried out in the flash memory 2. In a data deletion operation, data stored on a plurality of physical pages belonging to the same physical block are collectively deleted. In one example, each physical block includes 64, 128, or 256 physical pages. Note that the number of physical pages included in each physical block is increased in the latest flash memory such as 3D-NAND type flash memory.

Physical pages are processing units of data write operations and data read operations carried out in the flash memory 2. In data read operations and data write operations, memory cells are selected in units of physical pages, and data is written to the memory cells from the register or data is read from the memory cells to the register in units of physical pages.

One physical page includes 4, 8, or 16 physical sectors. Each physical sector is a region assigned to store 512 bytes of data (data of one sector). The data of one sector stored in each physical sector is stored together with the ECC (the error correcting code) of that data. The physical page may alternately assign a region that stores data of one sector and a region that stores an ECC corresponding to the data of that one sector. Alternatively, regions that store the data of four sections may be continuously assigned and, thereafter, regions that store ECCs corresponding to the data of those four sectors may be continuously assigned. That is, regions may be assigned such that the data of a plurality of sectors and the ECCs of that data are alternately stored in units of a few sectors.

The ECC (error correcting code) is data for detecting and correcting errors included in the data stored in each physical page.

Chip numbers CHIP #0, #1, #2 . . . , physical block numbers PB #0, #1, #2 . . . , physical page numbers PP #0, #1, #2 . . . , and physical sector numbers PS #0, #1, #2 . . . are respectively assigned as consecutive numbers to each chip, each physical block, each physical page, and each physical sector. These chip numbers, physical block numbers, physical page numbers, and physical sector numbers are used as physical addresses, which are pieces of information indicating the storage locations of the data stored in the flash memory 2.

Specifically, the chip numbers CHIP #0, #1, #2 . . . are numbers for identifying each chip in the flash memory 2. The physical block numbers PB #0, #1, #2 . . . are numbers for identifying each physical block in a chip. The physical page numbers PP #0, #1, #2 . . . are numbers for identifying each physical page in a physical block. The physical sector numbers PS #0, #1, #2 . . . are numbers for identifying each physical sector in a physical page.

Furthermore, it is possible to identify a physical block in the flash memory 2 by combining the chip number and the physical block number. For example, “CHIP #0, PB #1”, which is a number obtained by combining the chip number and the physical block number, corresponds to the physical block PB #1 of the plurality of physical blocks included in the chip CHIP #0. Likewise, it is possible to identify a physical page in the flash memory 2 by combining the chip number, the physical block number, and the physical page number. Moreover, it is possible to identify a physical sector in the flash memory 2 by combining the chip number, the physical block number, the physical page number, and the physical sector number.

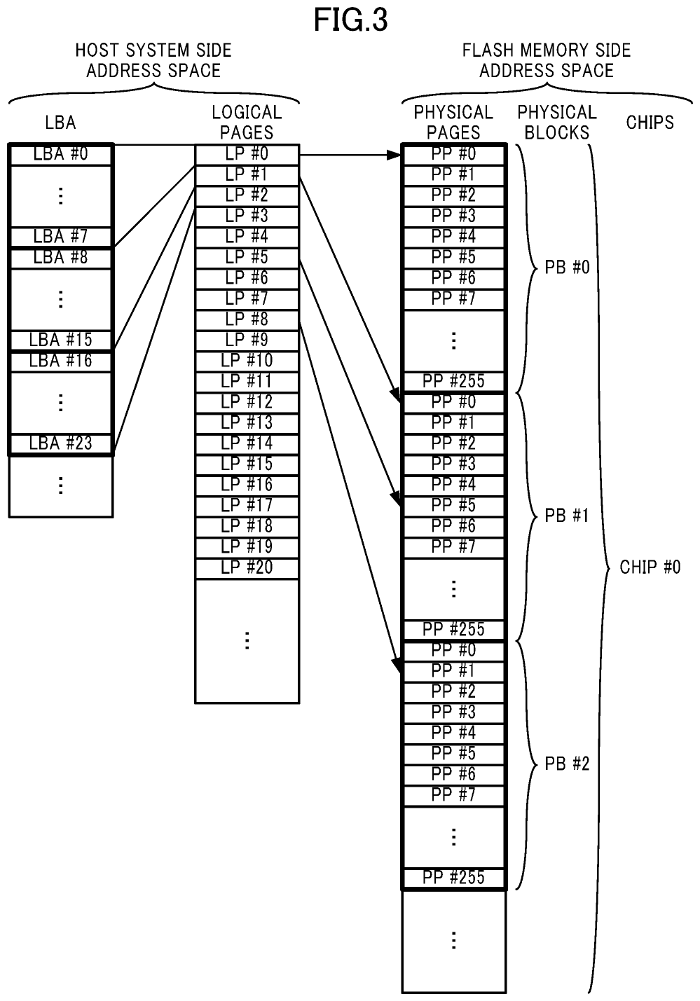

Next, the correspondences between logical addresses defined in address space on the host system 4 side and physical addresses defined in address space on the flash memory 2 side will be described while referencing FIG. 3. Here, the logical addresses are addresses that are managed in the host system 4 as information that identifies the data stored in the flash memory 2.

As illustrated in FIG. 3, in the address space on the host system 4 side, the logical addresses are defined using logical block addresses (LBA). An LBA is an address assigned to a logical sector that has a capacity of 512 bytes. An LBA number LBA #0, #1, #2 . . . is assigned to each LBA as a consecutive number. The host system 4 specifies the access region by the LBA. The memory controller 3 identifies the access region in the flash memory 2 based on the access region specified by the LBA.

The memory controller 3 defines a collection of a plurality of LBAs as a logical page. The logical pages correspond to the physical pages on the flash memory 2 side, and are processing units of data read operations and data write operations carried out on the host system 4 side. A logical page number LP #0, #1, #2 . . . is assigned to each logical page as a consecutive number. The logical page numbers LP #0, #1, #2 . . . correspond to addresses of the logical pages.

The number of LBAs assigned to one logical page is set so as to be equivalent to the number of physical sectors included in one physical page. In one example, in FIG. 3, the LBAs of LBA #0 to #7 are assigned to the logical page LP #0, the LBAs of LBA #8 to #15 are assigned to the logical page LP #1, and the like. Thus, eight LBAs are assigned per logical page. Since the LBAs and the logical pages are assigned in numerical order, the correspondences between the LBAs and the logical pages can be mutually converted by simple calculation.

The memory controller 3 carries out, in units of pages, address conversion to associate the logical addresses and the physical addresses. In other words, the memory controller 3 manages the addresses of the flash memory 2 using page mapping. Page mapping is an address management method in which the memory controller 3 combines pluralities of LBAs in units of logical pages.

In page mapping, the management unit is smaller than with block mapping, in which the addresses are managed in units of blocks. As such, while page mapping has a feature of higher random data writing performance than block mapping, an address conversion table in page mapping is larger than that in block mapping. In page mapping, when there is a data write request from the host system 4 of a size smaller than a page, processing is required in which the stored data is read, and a portion of the read data is replaced with new data.

Each logical page is assigned to one physical page included in the flash memory 2. For example, in FIG. 3, the logical page LP #0 is assigned to the physical page PP #0 of the physical block PB #0 in the CHIP #0. The logical page LP #1 is assigned to the physical page PP #0 of the physical block PB #1 in the CHIP #0. The logical page LP #5 is assigned to the physical page PP #5 of the physical block PB #1 in the CHIP #0.

As described above, the physical page is the unit of data reading and writing. As such, the memory controller 3 writes data corresponding to each logical page to the physical page associated with that logical page. However, the data on each physical page cannot be overwritten. Therefore, when only the data stored in a portion of the physical pages in a physical block is to be rewritten, the memory controller 3 must write the new data to an empty page (a different physical page to which data is not written) in that physical block, or to a different physical block.

That is, when the data stored in a portion of the physical pages in a physical block is to be rewritten, if there is not an empty page in that physical block, the memory controller 3 writes the new data to a different physical block. When, as a result of this rewriting, there are many physical pages storing old data (the data replaced by the new data) in that physical block, the data stored in the physical pages that are not to be rewritten may be transferred as-is to a different physical block to which data has not been written. As a result of this transferring, the transfer source physical block becomes an empty block, and becomes usable as a write destination physical block.

In order to avoid data corruption caused by the effects of retention (data retention), read disturb errors, and the like, and in order to level the number of deletions by static wear leveling, the data stored in each physical page in a physical block may be collectively transferred to a different physical block. The correspondences between the logical addresses and the physical addresses dynamically change due to this data rewriting and data transferring.

The memory controller 3 uses an address conversion table to manage the correspondences between the dynamically changing logical addresses and the physical addresses. The address conversion table is a table that defines the correspondences between the logical addresses and the physical addresses. The memory controller 3 references the address conversion table to convert a logical address, given by the host system 4, to a physical address, and identifies, based on the converted physical address, the storage location in the flash memory 2 of the data to be accessed.

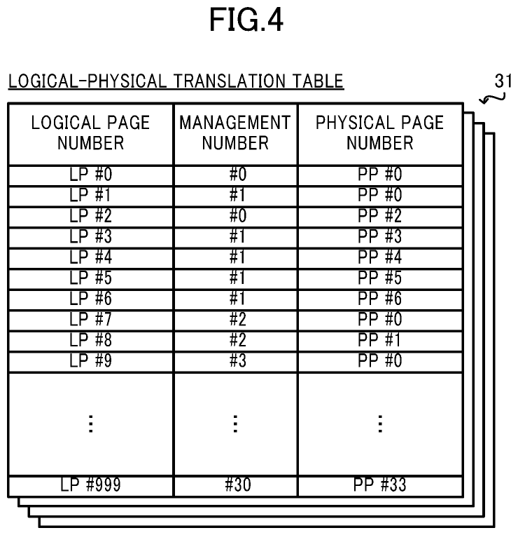

FIG. 4 and FIG. 5 illustrate specific examples of the address conversion table. The memory controller 3 uses two tables, namely a logical-physical translation table 31 illustrated in FIG. 4 and a management number table 32 illustrated in FIG. 5, as the address conversion table.

The logical-physical translation table 31 illustrated in FIG. 4 is a first table that defines the correspondence between the logical address and the physical address of each of the plurality of pieces of data stored in the flash memory 2. As described above, the memory controller 3 uses page mapping to manage the addresses and, as such, the logical-physical translation table 31 manages the correspondences between the logical addresses and the physical addresses based on the correspondences between the addresses of the logical pages (the logical page numbers) and the addresses of the physical pages (the physical page numbers).

Specifically, as illustrated in FIG. 4, the logical-physical translation table 31 defines, for each of the plurality of pieces of data stored in the flash memory 2, the correspondence between the logical page number, and a management number and the physical page number. The logical-physical translation table 31 uses the management number to manage which physical block of which chip each physical page belongs to. Accordingly, each physical page is identified by a combination of a management number and a physical page. In other words, in the logical-physical translation table 31, the physical page number represents the address of the physical page in the physical block to which the management number is assigned.

Here, the management number is a unique piece of management information that identifies each of the plurality of chips included in the flash memory 2, and is assigned such that it is possible to identify each of the plurality of physical blocks included in each chip. That is, each management number is associated with a combination of the chip number assigned to each of the plurality of chips and the physical block number assigned to each of the plurality of physical blocks. This association can be changed, as desired.

The management number table illustrated in FIG. 5 associates a management number with each of the plurality of physical blocks (the physical blocks included in the plurality of chips). As illustrated in FIG. 5, the management number table 32 is a second table that defines the correspondences between the management numbers, and the physical block numbers and the chip numbers defining each of the physical blocks included in the flash memory 2. Note that the memory controller 3 uses a number obtained by concatenating the chip number and the physical block number as the address (physical block address) of each of the physical blocks.

In the management number table 32, mutually different numbers are assigned, as the management numbers, to each of the plurality of physical blocks so that it is possible to identify each of the physical blocks included in the plurality of chips. That is, the management numbers are assigned such that it is possible to identify each of the physical blocks, regardless of which chip that physical block belongs to. In one example, in FIG. 5, the management number #0 is assigned to the physical block PB #0 in the chip CHIP #0, the management number #1 is assigned to the physical block PB #1 in the chip CHIP #0, and the management number #2 is assigned to the physical block PB #2 in the chip CHIP #0. Moreover, the management number #4096, which differs from that of the physical block PB #0 in the chip CHIP #0, is assigned to the physical block PB #0 in the chip CHIP #1.

The memory controller 3 creates such a management number table 32 by assigning mutually different management numbers to each of the plurality of physical blocks in the flash memory 2. The number of rows of the management number table 32 corresponds to the number of physical blocks included in the flash memory 2. For example, in a case in which the flash memory 2 includes m chips that include n physical blocks per chip, the number of management numbers defined in the management number table 32 (the number of rows of the management number table 32) is (m×n).

In contrast, the number of rows of the logical-physical translation table 31 depends on the capacity of the flash memory system 1 (the capacity of data that can be saved), and substantially matches the number of physical pages included in the physical blocks used as data storage destinations in the flash memory 2. For example, if each physical block includes 256 physical pages, the number of rows of the logical-physical translation table 31 is about 256-times the number of management numbers. This results in the table size of the logical-physical translation table 31 being much larger than the table size of the management number table 32.

Therefore, the logical-physical translation table 31 is divided into a plurality of sub-tables, each including a predetermined number of logical pages. In one example, in FIG. 4, the logical-physical translation table 31 is divided every 1000 logical pages in order of logical page numbers into a plurality of tables, and managed. For example, the logical page numbers LP #0 to #999 are recorded in a first table, the logical page numbers #1000 to #1999 are recorded in a second table, and the like.

The logical-physical translation table 31 and the management number table 32 described above are read from the flash memory 2 into the SRAM 8 at start-up or at a time of access. The memory controller 3 updates the logical-physical translation table 31 or the management number table 32 on the SRAM 8. The logical-physical translation table 31 or the management number table 32 updated on the SRAM 8 is written to the flash memory 2. Note that the writing to the flash memory 2 is performed for each of the divided tables. That is, in a case in which the first table of the logical-physical translation table 31 is updated on the SRAM 8, that updated first table is written to the flash memory 2.

In the memory controller 3, when accessing the flash memory 2, the microprocessor 6 identifies the correspondence between the logical address and the physical address by referencing the logical-physical translation table 31 and the management number table 32 described above. Specifically, the microprocessor 6 executes access processing for controlling access to the flash memory 2 and region management for managing a storage region in accordance with the access processing.

In the access processing, the memory controller 3 controls the access to the flash memory 2 in response to commands from the host system 4. Specifically, the memory controller 3 controls processing for reading and deleting data stored in the flash memory 2, writing data to the flash memory 2, and the like.

The memory controller 3 identifies, based on the logical-physical translation table 31 and the management number table 32, the physical address representing the storage location in the flash memory 2 of the data to be accessed. Specifically, when an instruction for data reading, data rewriting, or the like by an external command is received from the host system 4, the memory controller 3 references the logical-physical translation table 31 and the management number table 32 to convert the logical address to be accessed instructed by the host system 4 to a physical address. Then, the memory controller 3 executes processing for data reading, data writing, or the like with the physical page identified by the converted physical address as the storage location of the data to be accessed.

More specifically, the memory controller 3 identifies, based on the management number associated with each of the plurality of physical blocks included in the flash memory 2, the physical block in the flash memory 2 to be accessed.

For example, in a case in which data is to be read from the flash memory 2, when the memory controller 3 is provided, by the host system 4, with a logical page number that is the address of the logical page to be read, that logical page number is converted to a physical page number and a management number based on the logical-physical translation table 31. As a result, the memory controller 3 identifies the physical page number and the management number corresponding to the logical page provided by the host system 4. Next, the memory controller 3 converts the management number to a chip number and a physical block number based on the management number table 32. As a result, the memory controller 3 identifies the physical block corresponding to the management number identified based on the logical-physical translation table 31.

When the physical block to be accessed is identified in this manner, the memory controller 3 determines, as the physical page to be read, the physical page, identified based on the logical-physical translation table 31, in the physical block identified based on the management number table 32. Then, the memory controller 3 accesses the identified physical page. The data stored in the identified physical page is read to the buffer 9 via the register in the flash memory 2, and provided to the host system 4.

In addition to cases in which data is read from the flash memory 2, in cases in which data is written to the flash memory 2, the memory controller 3 identifies, based on the logical-physical translation table 31 and the management number table 32, the physical page that is the storage location in the flash memory 2 of the data to be accessed.

In the region management, the memory controller 3 updates the logical-physical translation table 31 or the management number table 32 in accordance with the access processing performed on the flash memory 2. Specifically, the memory controller 3 updates the logical-physical translation table 31 when processing for writing data to the flash memory 2 is performed, and updates the management number table 32 when data is transferred between different physical blocks.

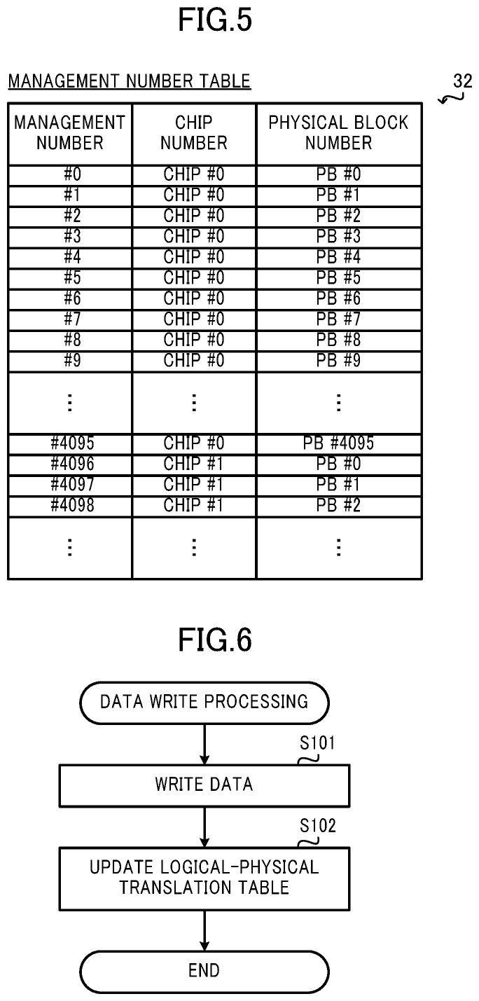

First, the memory controller 3 updates the logical-physical translation table 31 when processing for writing data to the flash memory 2 is performed. Hereinafter, data write processing will be described while referencing the flowchart illustrated in FIG. 6.

The data write processing illustrated in FIG. 6 is processing in which data supplied from the host system 4 is written to the flash memory 2. In this data writing, a number of sectors of data to be written, a head value of the LBAs of the data to be written, and an external command instructing the write processing are supplied together with write data to the memory controller 3 via the host interface block 7.

In the data write processing illustrated in FIG. 6, the memory controller 3 writes the write data supplied from the host system 4 to the flash memory 2 (step S101). Specifically, the memory controller 3 supplies, to the flash memory 2, the address of the physical page of the write destination and an internal command instructing the write processing. In addition, the memory controller 3 transfers, to the register in the flash memory 2, the data supplied from the host system 4. The transferred data is held in the register and, then, is written to the physical page of the write destination corresponding to the address provided from the memory controller 3.

The memory controller 3 updates the logical-physical translation table 31 when the processing for writing the data to the flash memory 2 is performed (step S102). Specifically, when the processing for writing the data to be written to the flash memory 2 is performed, the memory controller 3 updates the physical page number and the management number associated with the logical page number of the data to be written. In this updating, the memory controller 3 identifies, in the management number table 32, the management number associated with the physical block that includes the physical page to which the data to be written is written. Then, the memory controller 3 adds, to the logical-physical translation table 31, a new correspondence in which that management number and the physical page number of the physical page to which the data is written are associated with the logical page number of the data to be written.

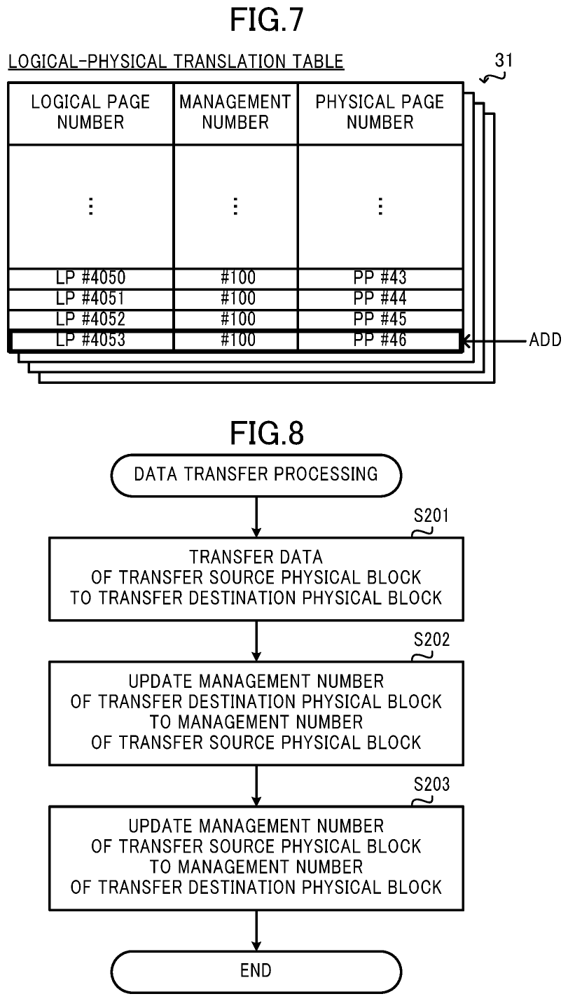

For example, FIG. 7 illustrates an example in which the logical-physical translation table 31 is updated in a case in which data corresponding to the logical page having the logical page number LP #4053 is written to the physical page having the physical page number PP #46 in the physical block to which the management number #100 is assigned in the management number table 32. In this case, the memory controller 3 adds, to the logical-physical translation table 31, a new correspondence in which the logical page number #4053, and the management number #100 and the physical page number PP #46 are associated. As a result, the logical-physical translation table 31 is updated to a latest state after the data to be written is stored in the flash memory 2.

At this time, in a case in which the data to be written is written to a plurality of physical pages, the memory controller 3 adds, to the logical-physical translation table 31, a correspondence for each of the plurality of physical pages in which the logical page, and the management number and the physical page number are associated.

As described above, the logical-physical translation table 31 is divided into a plurality of sub-tables, each including a predetermined number of logical pages. As such, the memory controller 3 updates only the relevant sub-table of the plurality of sub-tables of the logical-physical translation table 31, and does not update the other sub-tables. For example, in the case illustrated in FIG. 7, the memory controller 3 adds a new correspondence to the sub-table, in which the correspondence related to the logical page number #4053 is to be recorded, of the plurality of sub-tables of the logical-physical translation table 31.

After adding the new correspondence to the logical-physical translation table 31 as described above, the memory controller 3 identifies, based on the logical-physical translation table 31 to which the new correspondence is added and the management number table 32, the storage location in the flash memory 2 of the data to be accessed. Thus, the data write processing illustrated in FIG. 6 is ended.

Second, the memory controller 3 updates the management number table 32 when data is transferred between different physical blocks in the flash memory 2. Hereinafter, data transfer processing will be described while referencing the flowchart illustrated in FIG. 8.

The data transfer processing illustrated in FIG. 8 is processing in which the data stored in one physical block of the plurality of physical blocks included in the flash memory 2 is transferred to a different physical block. In the data transfer processing, the memory controller 3 transfers the data stored in a transfer source physical block to a transfer destination physical block (step S201).

In the data transfer processing, in order to avoid data corruption caused by the effects of retention (data retention), read disturb errors, and the like, all of the data in a physical block is transferred as-is to a different physical block.

In cases in which, among the plurality of physical blocks included in the flash memory 2, a physical block exists for which an indicator, that indicates a degree of risk of data corruption, satisfies a predetermined condition, all of the data stored in that physical block is transferred as-is to a different physical block. At this time, the memory controller 3 transfers the data so that same data is stored in the physical page that has the same physical page number in the transfer source physical block and in the transfer destination physical block.

When the data is transferred between physical blocks in this manner, the memory controller 3 updates, in the management number table 32, the management number associated with the transfer destination physical block to the management number associated with the address of the transfer source physical block (step S202). Furthermore, the memory controller 3 updates, in the management number table 32, the management number associated with the transfer source physical block to the management number associated with the transfer destination physical block (step S203).

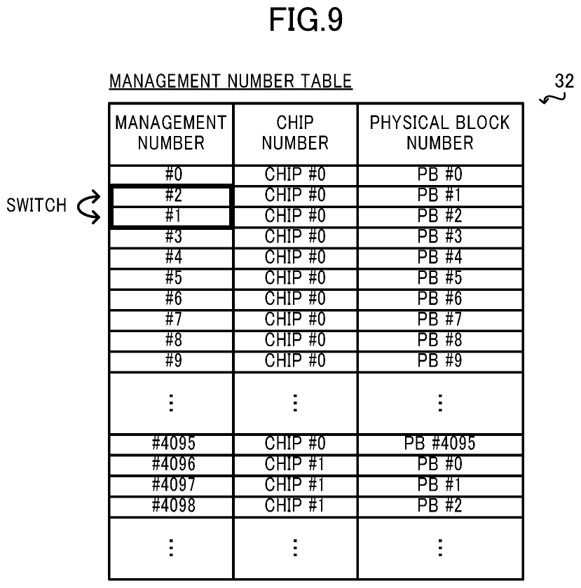

For example, FIG. 9 illustrates an example in which the management number table 32 is updated. In this case, in the management number table 32 illustrated in FIG. 5, the management number #1 is associated with the chip number CHIP #0 and the physical block number PB #1, and the management number #2 is associated with the chip number CHIP #0 and the physical block number PB #2. In contrast, in a case in which the data is transferred from the physical block PB #1 in the chip CHIP #0 to the physical block PB #2 in the same chip, the memory controller 3 updates the management number table 32 as illustrated in FIG. 9.

Specifically, the memory controller 3 updates the management number #2 associated with the address “CHIP #0, PB #2” of the transfer destination physical block to the management number #1 associated with the address “CHIP #0, PB #1” of the transfer source physical block. Then, the memory controller 3 updates the management number #1 assigned to the address “CHIP #0, PB #1” of the transfer source physical block to the management number #2 assigned to the address “CHIP #0, PB #2” of the transfer destination physical block. In other words, the memory controller 3 switches the management number #1 associated with the transfer source physical block and the management number #2 associated with the transfer destination physical block in the correspondences between the management numbers and the physical blocks (the chip numbers and the physical block numbers) defined in the management number table 32.

By changing the management number associated with the transfer source physical block to the management number associated with the transfer destination physical block in this manner, the management number associated with the physical block in which the transferred data is stored is the same before and after the transfer. As such, when performing the data transfer processing, the memory controller 3 does not need to update the logical-physical translation table 31 if the management number table 32 is updated. That is, in the management number table 32, if the management number associated with the transfer destination physical block and the management number associated with the transfer source physical block are updated, there is no need to update the correspondences, in the logical-physical translation table 31, related to the logical pages corresponding to the transferred data. If, for example, the logical-physical translation table 31 is created without management numbers, correspondences related to the logical page numbers equivalent to the number of pages of transferred data must be updated. For example, in a case in which one physical block includes 256 physical pages, 256 correspondences must be updated when the data stored in all of the pages is transferred. Additionally, even after the data is transferred between the physical blocks, the memory controller 3 can access that data using the same logical-physical translation table 31 as before the transfer. Thus, the data transfer processing illustrated in FIG. 8 is ended.

As described above, the memory controller 3 according to the present embodiment identifies the physical block to be accessed based on the management numbers associated with the plurality of physical blocks included in the flash memory 2. In a case in which the data stored in one physical block of the plurality of physical blocks is transferred to a different physical block, the memory controller 3 changes the management number associated with the different physical block to the management number associated with the one physical block. By identifying the physical blocks using the management numbers in this manner, in a case in which the data is transferred between different physical blocks, provided that the management numbers associated with the physical blocks related to the transferred data are updated, there is no need to update the correspondences related to all of the logical page numbers corresponding to the transferred data. As a result, it is possible to efficiently manage the addresses when data is transferred between the physical blocks.

In particular, in a case in which the logical-physical translation table 31 is divided into a plurality of sub-tables and the logical page numbers corresponding to each piece of data stored in the plurality of physical pages included in one physical block are not continuous, the correspondences related to those logical page numbers may be divided and managed in different sub-tables. In such a case, when the data of that physical block is transferred to the different physical block, all of the sub-tables in which the correspondences, related to the logical page numbers corresponding to the transferred data, are defined must be updated. For example, in a case in which one physical block includes 256 physical pages, the memory controller 3 must, at maximum, open 256 different sub-tables and update the correspondences. Due to this, not only does processing performance decline, but the number of rewrites of the flash memory 2 increases, which shortens the life of the flash memory 2.

In cases in which data is transferred between physical blocks, the memory controller 3 according to the present embodiment does not need to update the logical-physical translation table 31 that is divided into a plurality of sub-tables, and it is sufficient only to switch the management numbers, in the management number table 32, of the transfer source physical block and the transfer destination physical block. As such, it is possible to efficiently manage the addresses when data is transferred between the physical blocks.

### MODIFIED EXAMPLES

Embodiments of the present disclosure are described above, but these embodiments are merely examples and do not limit the scope of application of the present disclosure. That is, various applications of the embodiments of the present disclosure are possible, and all embodiments are included in the scope of the present disclosure.

For example, in the embodiment described above, the logical-physical translation table 31 and the management number table 32 are created and updated on the SRAM 8 of the memory controller 3 and are stored in the flash memory 2. However, a configuration is possible in which the logical-physical translation table 31 and the management number table 32 are stored outside of the flash memory 2 (on a different non-volatile memory). Additionally, a configuration is possible in which the logical-physical translation table 31 and the management number table 32 are created and updated on a different non-volatile memory.

A configuration is possible in which the correspondences between the logical addresses and the physical addresses, and the correspondences between the management numbers and the physical blocks are defined in formats other than the logical-physical translation table 31 and the management number table 32 as in the embodiment described above. Additionally, a configuration is possible in which these correspondences are not defined in the format of tables.

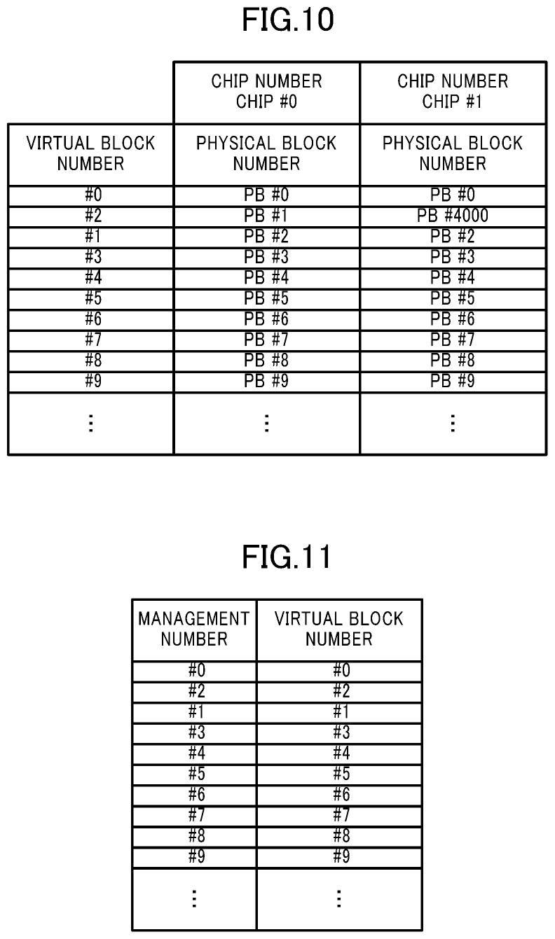

A configuration is possible in which, when managing a plurality of physical blocks as a single virtual block, a management number is assigned to that virtual block. For example, as illustrated in FIG. 10, a configuration is possible in which virtual blocks are constituted from the physical blocks in the chip number CHIP #0 and the physical blocks in the chip number CHIP #1, and management numbers are assigned to these virtual blocks as illustrated in FIG. 11. In this example, a virtual block having a virtual block number #0 is constituted from the physical block having the physical block number PB #0 in the chip number CHIP #0 and the physical block having the physical block number PB #0 in the chip number CHIP #1, and a management number #0 is assigned to this virtual block having the virtual block number #0. Note that, in this virtual block, virtual pages are constituted from the physical pages included in a physical block in the chip number CHIP #0 and the physical pages included in a physical block in the chip number CHIP #1. That is, a virtual page is constituted from the physical page having the physical page number PP #0 included in the physical block having the physical block number PB #0 in the chip number CHIP #0, and the physical page having the physical page number PP #0 included in the physical block having the physical block number PB #0 in the chip number CHIP #1.

The number of physical blocks included in each chip, the number of physical pages included in each physical block, the number of physical sectors included in each physical page, the number of LBAs included in each logical page and the like in the embodiment described above are only given as examples, and the present disclosure is not limited thereto. Moreover, in the embodiment described above, an example is described in which the flash memory 2 includes a plurality of chips but, in the present disclosure, a configuration is possible in which the flash memory 2 includes one chip.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

What is claimed is:

1. A memory controller that controls access to a flash memory in response to a command from a host system, the memory controller comprising:
a microprocessor that executes access processing for controlling the access to the flash memory and region management for managing a storage region in accordance with the access processing; wherein
in the access processing, a physical block to be accessed among a plurality of physical blocks included in the flash memory is identified based on management information associated with each of the plurality of physical blocks, and
in the region management, when data stored in one physical block among the plurality of physical blocks is transferred to a different physical block among the plurality of physical blocks that is different from the one physical block, management information associated with the different physical block is changed to management information associated with the one physical block.

2. The memory controller according to claim 1, wherein
in the access processing, a storage location of data to be accessed in the flash memory is identified based on a first table that defines, using the management information, a correspondence between a logical address corresponding to each piece of data stored in the flash memory and a storage location of the each piece of data, and a second table that defines correspondences between the plurality of physical blocks and the management information, and
in the region management, when the data stored in the one physical block is transferred to the different physical block, the management information associated with the different physical block in the second table is changed to the management information associated with the one physical block.

3. The memory controller according to claim 2, wherein
the first table defines, using the management information, the correspondence between a logical page corresponding to the each piece of data and a physical page on which the each piece of data is stored, and
in the access processing, a physical block including the physical page corresponding to the logical page to be accessed is identified based on the second table, and the physical page is accessed.

4. A flash memory system, comprising the memory controller according to claim 1; and the flash memory.
